(19) United States
(12) Patent Application Publication
(10) Pub. No.: US 2012/0057392 A1
(43) Pub. Date: Mar. 8, 2012

(54) High Density Non-Volatile Information StorageHigh Density Non-Volatile information Storage

(75) Inventors: Daryl C. Chrzan, Lafayette, CA (US); Joel W. Ager, Berkeley, CA (US); Eugene E. Haller, Berkeley, CA (US)

(73) Assignee: The Regents of the University of California, Oakland, CA (US)

(21) Appl. No.: 13/294,431

(22) Filed: Nov. 11, 2011

Related U.S. Application Data
(63) Continuation of application No. PCT/US2010/034807, filed on May 13, 2010.
(60) Provisional application No. 61/177,857, filed on May 13, 2009.

(51) Int. Cl. G11C 11/00; H01B 1/02

(52) U.S. Cl. 365/148; 252/512

(57) ABSTRACT

The present invention provides for a composition comprising a nanostructure comprising a semiconductor component and a metallic component, with the proviso that when the semiconductor component is Ge the metallic component is not Te. The nanostructure can be in one of two types of structures: (1) a segregated structure, and (2) a mixed structure. In the segregated structure, the semiconductor component and the metallic component are spatially separate, such as in a lobe-lobe structure, poly-lobe structure, or a core-shell structure. In some embodiments, the lobe-lobe structure comprises a metallic component lobe and a semiconductor component lobe. The composition can be used in a memory device.

### RELATED PATENT APPLICATIONS

The application claims priority as a continuation application to PCT International Patent Application No. PCT/US2010/34807, filed May 13, 2010, which claims priority to U.S. Provisional Patent Application Ser. No. 61/177,857, filed May 13, 2009, which are herein incorporated by reference in their entireties.

### STATEMENT OF GOVERNMENTAL SUPPORT

This invention was made with government support under Contract No. DE-AC02-05CH11231 awarded by the U.S. Department of Energy. The government has certain rights in the invention.

### FIELD OF THE INVENTION

The present invention is in the field of digital information storage.

### BACKGROUND OF THE INVENTION

As an alternative to the scaling limits of floating gate technology, solid-state static random access memory technology has been moving in the direction of phase change memories. Ongoing research suggests that memory may be fabricated by employing the resistivity change associated with a phase change between a crystalline and an amorphous state. The resistivity of the material stores the state of the bit. Currently, the phase change is accomplished with resistive heating and a special material, for example, a Ge-Sb-Te alloy. This technology is similar to what is used commercially for CD R/W applications and research is focused on integrating the idea with complementary metal-oxide-semiconductor (CMOS) addressing schemes and determining the scaling limits and reliability.

### SUMMARY OF THE INVENTION

The present invention provides for a composition comprising a nanostructure comprising a semiconductor component and a metallic component, with the proviso that when the semiconductor component is Ge the metallic component is not Te. Each component can comprise a chemical element or a chemical compound. The term “semiconductor component” refers to a semiconductor that is pure, compound or doped), or an insulating element or compound, and the term “metallic component” refers to a pure metal, metallic compound or alloy, or a degenerate semiconductor.

The nanostructure of the present invention can be in one of two types of structures: (1) a segregated structure, and (2) a mixed structure. In the segregated structure, the semiconductor component and the metallic component are spatially separate, such as in a lobe-lobe structure, poly-lobe structure, or a core-shell structure. In some embodiments, the lobe-lobe structure comprises a metallic component lobe and a semiconductor component lobe. In some embodiments, the core-shell structure comprises a metallic component core and a semiconductor component shell. In the mixed structure, the two components are intermixed, such as in a random binary solid solution or a homogenized mixed structure, which is a highly resistive material or is amorphous. In some embodiments, the nanostructures are nanocrystals and/or nanowires.

One or more of the physical properties, such as electrical resistance and thermal resistance, of the segregated and mixed structures can be made to vary greatly between the segregated and mixed structures. The semiconductor and metallic components can be chosen to tune desired properties, such as resistivity, equilibrium melting point, and solidification kinetics, of the segregated and mixed structures.

The present invention also provides for a method of changing the nanostructure from a segregated to a mixed structure and/or vice versa. This can be performed by imposition of many different influences including, but not limited to, heat, light, stress, particle radiation, and currents.

The present invention provides for a method comprising: (a) providing a composition of the present invention wherein the nanostructure is in a first structure, (b) rapid heating of the nanostructure, and (c) cooling in a controlled manner such that the nanostructure is converted into a second structure, wherein the cooling step comprises a gradual cooling or a rapid cooling. In some embodiments, the first structure is a segregated structure, the second structure is a mixed structure, and the cooling step comprises a rapid cooling. In other embodiments, the first structure is a mixed structure, the second structure is a segregated structure, and the cooling step comprises a gradual cooling.

The present invention provides for a memory device comprising the composition of the present invention. In embodiments, the memory device is recordable or rewritable. Each bit can be composed of a single or multiple nanostructures. The state of the bit may be stored, for example, in the resistivity of the nanostructure. The bit information is stored in the resistivity of the nanostructures comprising the bit. The state of each nanostructure is either segregated or mixed, and the resistivity depends on the state of the nanostructure.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 shows an example of the type of memory of the present invention. The solid block is a conducting glass containing nanoparticles. The nanoparticles comprise of an alloy miscible in the liquid phase and strongly segregating in the solid phase. These nanoparticles can exist in two states with different conductivities. The equilibrium state is a core-shell structure (exploded view, right). The alloyed state is obtained by quenching the liquid phase (exploded view, left). The memory bits are addressed and set using the contacts shown in black. The bit addressed is defined by the choice of the wires addressed. The bit state is stored in the resistivities of the material between the contact pair.

FIG. 2 shows schematic current pulses. A pulse of type (a) will yield the random alloy high resistivity nanoparticle phase. A pulse of type (b) will yield the equilibrium phase for the nanoparticles.

FIG. 3 shows three Ge-Sn nanostructures produced using ion beam synthesis observed using Z-contrast TEM. The images are processed such that Ge regions are purple, Sn atoms are red. The structures formed directly by IBS have a Ge-lobe/Sn-lobe structure. Application of pulsed laser melting leads to nanocluster that is a homogeneous mixture of Ge and Sn. Subsequent rapid thermal annealing leads to a Sn-core/Ge-shell structure.

FIG. 4 shows examples of eutectic semiconductor/metal nanowire structures for use as phase change memory devices. The nanowires are embedded within a matrix material (not shown). (A) The core/shell structure. Since the metal is continuous between the top and the bottom of the ends of the wire, the resistivity of these wires will be minimal. (B) Homogeneous alloy nanowires. These are produced from the wires in (A) by melting, and then quenching rapidly. These wires are expected to have a substantially higher resistance than those in (A). (C) shows a disk multi-layer structure is another semiconductor/metal nanowire structure that is also useful in a phase change memory device.

FIG. 5 shows Z-contrast STEM image of Ge-Sn alloy nanocrystals. Bright regions and dark regions correspond to Sn and Ge (or to Sn and Ge rich phases), respectively.

FIG. 6 shows a high resolution image of an alloy nanocrystal. Crystalline lattice structure can be seen.

FIG. 7 shows a Z-contrast STEM image of Ge-Sn alloy nanocrystals. Bright regions and dark regions correspond to Sn and Ge (or to Sn and Ge rich phases), respectively.

FIG. 8 shows a high resolution image of a Ge-Sn alloy nanocrystal. Crystalline lattice structure can be seen.

### DETAILED DESCRIPTION OF THE INVENTION

Before the invention is described in detail, it is to be understood that, unless otherwise indicated, this invention is not limited to particular sequences, expression vectors, enzymes, host microorganisms, or processes, as such may vary. It is also to be understood that the terminology used herein is for purposes of describing particular embodiments only, and is not intended to be limiting.

As used in the specification and the appended claims, the singular forms “a,” “an,” and “the” include plural referents unless the context clearly dictates otherwise. Thus, for example, reference to a “nanoparticle” includes a single nanoparticle as well as a plurality of nanoparticles, either the same (i.e., the same metallic component-semiconductor component combination) or different (i.e., different metallic component-semiconductor component combinations).

In this specification and in the claims that follow, reference will be made to a number of terms that shall be defined to have the following meanings:

The terms “optional” or “optionally” as used herein mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

### Nanostructures of the Invention

The two components may have a low melting point, are miscible in the liquid state and able to segregate in the solid phase. In some embodiments, the two components are in a ratio such that the two components form or nearly form a eutectic alloy. In some embodiments, the nanostructure consists essentially of the semiconductor component and the metallic component. The ratio of each metallic components-semiconductor components pair to form or nearly form a eutectic alloy can be determined using methods well known in the art.

In some embodiments, the composition further comprises a matrix wherein the nanoparticle is embedded within the matrix. In some embodiments, the matrix comprises a plurality or an array of the nanostructures, wherein each nanostructure is independently a lobe-lobe structure, mixed structure, or a core-shell structure. In some embodiments, the matrix comprises SiO₂, HfO, Al₂O₃, a glass, or any doped variety thereof. In some embodiments, matrix consists essentially of SiO₂ or a glass. In some embodiments, the matrix is transparent, translucent, or essentially transparent.

In some embodiments, the composition comprises one or more nanoparticles comprising Ge and Sn in a suitable matrix, wherein each nanostructure is independently a Ge lobe-Sn lobe structure, Sn-Ge mixed structure, or a Sn core-Ge shell structure. In some embodiments, the matrix comprises SiO₂ or a glass. The nanoparticles comprise Ge lobe-Sn lobe structure, mixed structure, and/or Sn core-Ge shell structures.

In some embodiments, the composition comprises a plurality or an array of the nanostructures. In some embodiments, the ratio of the semiconductor components to the metallic components in each plurality of nanostructures is substantially equal. In some embodiments, the nanostructure is a two-phase nanocrystal, wherein the two components form a low melting point eutectic. In some embodiments, the low melting point eutectic is a temperature less than 1,000° C. In some embodiments, the low melting point eutectic is a temperature less than 750° C. In some embodiments, the low melting point eutectic is a temperature is about equal to or less than 500° C.

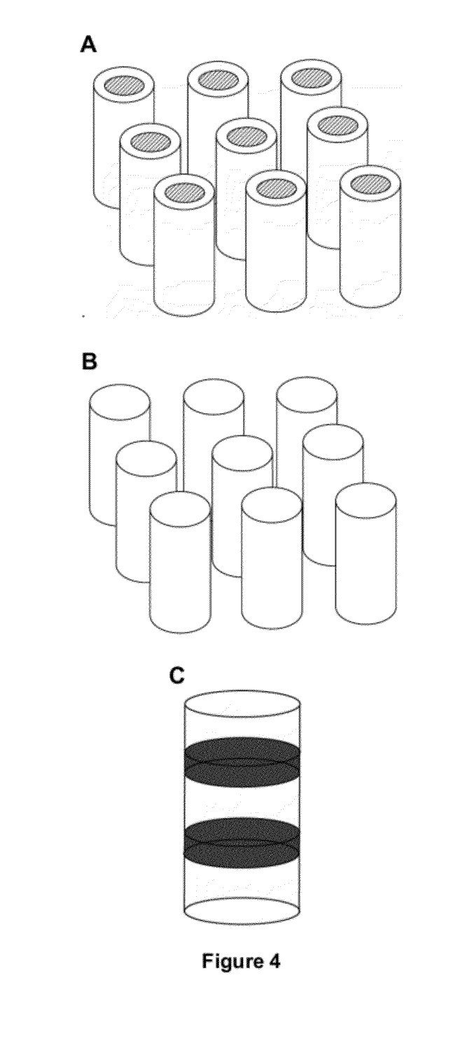

In some embodiments, the nanostructure comprises a lobe-lobe structure, wherein nanostructure has a plurality of lobes, wherein each lobe comprises either the metallic component or semiconductor component. In some embodiments, the nanostructure comprises a core-shell structure, wherein the shell surrounds or envelopes or covers the core, and the shell comprises the metallic component and the core comprises the semiconductor component. In some embodiments, the nanostructure is of an amorphous structure. When the nanostructure is a nanowire, the lobe-lobe structure refers to a nanowire wherein each component runs the entire length of the nanwire. When the nanostructure is a nanowire, the core-shell structure refers to a nanowire wherein a first component forms the heart of the nanowire and the second component envelops the first component except at the two ends of the nanowire (FIG. 4A). Another embodiment of the nanowire is a disk multi-layer structure that is also useful in a phase change memory device (FIG. 4C). A method for making a disk multi-layer structure is taught by Chueh et al., “Nanoscale structural engineering via phase segregation: Au-Ge system”, NanoLetters 10, 393-397 (2010), hereby incorporated by reference.

In some embodiments, the ratio of the amount of the semiconductor component and the metallic component is such that the semiconductor component and the metallic component form an eutectic alloy. In some embodiments, the ratio of the amount of the semiconductor element and the metal element is from about 2 to about 8, from about 3 to about 5, or from about 3.5 to about 4.5. In some embodiments, the ratio of the amount of the semiconductor component and the metallic component is about 4.

In some embodiments, the semiconductor component is a Group IV semiconductor. In some embodiments, the semiconductor component is Si, Ge, C (diamond), SiC, GaN, GaAs, InN, CdSe, or ZnO. In some embodiments, the semiconductor component is Ge. In some embodiments, the metallic component is Sn, Au, Ag, Al, or Cu. In some embodiments, the semiconductor component is Ge and the metallic component is Sn. In some embodiments, the nanostructure is a nanoparticle or a nanowire.

Suitable semiconductor component-metallic component combinations are described in Table 1.

TABLE 1
Suitable semiconductor component-metallic component combinations.

| | | Metallic component | | | | |
|---|---|---|---|---|---|---|
| | | Sn | Au | Ag | Al | Cu |
| Semiconductor | Si | Si—Sn | Si—Au | Si—Ag | Si—Al | Si—Cu |
| component | Ge | Ge—Sn | Ge—Au | Ge—Ag | Ge—Al | Ge—Cu |
| | C (diamond) | C—Sn | C—Au | C—Ag | C—Al | C—Cu |
| | SiC | SiC—Sn | SiC—Au | SiC—Ag | SiC—Al | SiC—Cu |
| | GaN | GaN—Sn | GaN—Au | GaN—Ag | GaN—Al | GaN—Cu |
| | GaAs | GaAs—Sn | GaAs—Au | GaAs—Ag | GaAs—Al | GaAs—Cu |
| | InN | InN—Sn | InN—Au | InN—Ag | InN—Al | InN—Cu |
| | CdSe | CdSe—Sn | CdSe—Au | CdSe—Ag | CdSe—Al | CdSe—Cu |
| | ZnO | ZnO—Sn | ZnO—Au | ZnO—Ag | ZnO—Al | ZnO—Cu |

In some embodiments, the semiconductor component and the metallic component are distinctly separate within the nanostructure. In some embodiments, the semiconductor component and the metallic component are intermixed in or constitute an alloy.

Xu et al., recently reported germanium nanocrystals embedded in silica that exhibit a large hysteresis in their melting/freezing phase transition. That is, solid nanocrystals are stable at temperatures far above the bulk melting point (+200 K), but, once melted, the nanoclusters remain liquid to well below the bulk freezing temperature (−200 K). (Q. Xu, I. D. Sharp, C. W. Yuan, D. O. Yi, C. Y. Liao, A. M. Glaeser, A. M. Minor, J. W. Beeman, M. C. Ridgway, P. Kluth, J. W. Ager III, D. C. Chrzan, and E. E. Haller, “Large melting point hysteresis of Ge nanocrystals embedded in SiO₂,” Phys Rev. Lett. 97, 155701 (2006); herein incorporated by reference). However, the hysteresis of Ge nanocrystals in silica is not suitable for digital memory applications because the melting point of the nanocrystals is too high, over 1100° C. The present invention utilizes a result of considering the melting behavior of 2-phase nanocrystals, specifically those in which the two components form a low melting point eutectic. The present invention is based on the melting point hysteresis behavior of embedded nanocrystals and the known phase diagrams for low-melting point eutectic compounds. The embedded nanocrystals can be used based on the metastability of core/shell to random phase transition, and can be used as a solid state non-volatile memory.

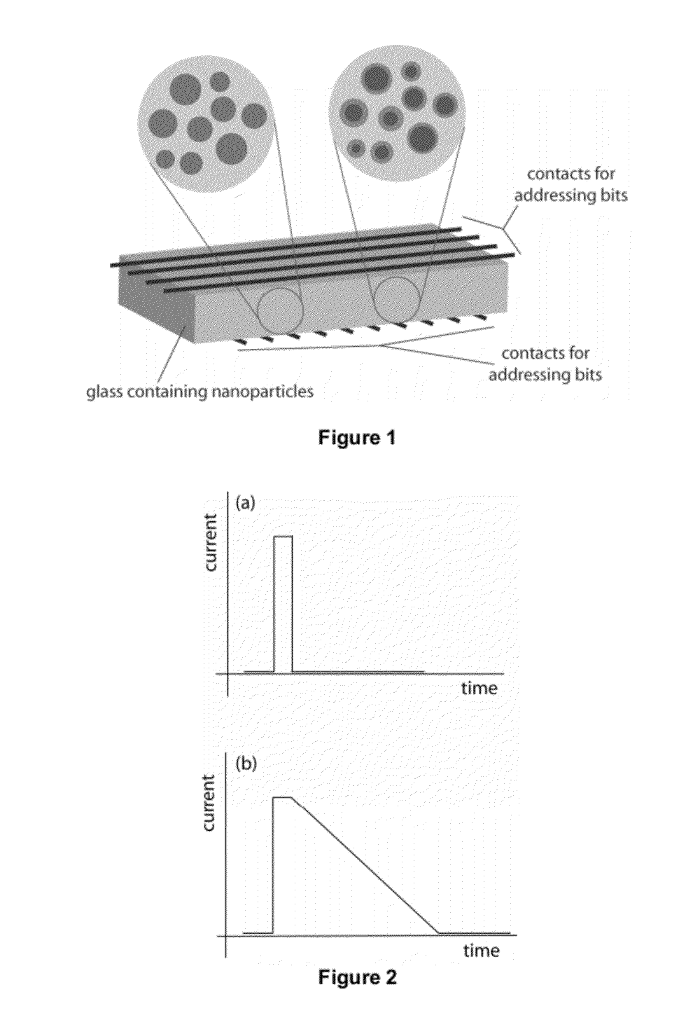

FIG. 1 shows core-shell nanoparticles as the main component of a phase-change static memory device. In some embodiments, the core material is semiconducting or insulating, whereas the shell material is metallic or a degenerate semiconductor. A metallic core and insulating shell may also provide the necessary change in resistivity.

The core-shell nanoparticles can exist in two states. In the equilibrium state, the core and shell materials are separated, and the nanoparticles consist of a conducting outer layer with an insulating or semiconducting core. This is the low resistivity phase of the material. In the kinetically limited state, the nanoparticles consist of a random binary solid solution (possibly amorphous) producing a high resistivity material.

The nanoparticle materials should be chosen to have a low melting point, be miscible in the liquid state, and be strongly segregating in the solid phase. Eutectic alloys, for example, Ge-Au, can suit the purposes. Alternatively, strongly segregating alloys with a low melting point that do not display a eutectic, for example Ge-Sn, can be employed.

Nanocrystals will be embedded in a conducting glass, for example doped ZnO, so that the resistance properties are ohmic in nature. The transition to the random binary alloy (possibly amorphous) phase will be accomplished via a brief current pulse (FIG. 2). The subsequent solidification is so rapid that the nanocrystals will freeze in the disordered state. A more drawn out current pulse will yield the equilibrium core/shell structure. The optically transparent glass embedding material allows for the use of laser light to fine tune the melting/freezing kinetics if so desired. Further, the stability of the nanoparticle/glass matrix system will enhance repeated read/write reliability for the devices.

The nanoparticles may be fabricated in a variety of shapes ranging from rods spheres to rods. Other embedding schemes might be considered, including the filling of pores in alumina or porous SiC. The invention is scalable, presumably down to the scale of a few, or even one nanoparticle per bit. The nanoaprticles can be made suing the method described in Xu, et al. (2006), and the method described in Example 1 herein.

### The Dimensions of the Nanostructure

The nanoparticle and nanowire each have at least one dimension that is limited from 2 nm to 1,000 nm in length. In certain embodiments, the plurality of nanostructures is of a population of nanostructures having substantially monodisperse distribution of diameters and/or lengths. For nanoparticles, the term “diameter” refers to the effective diameter, as defined by the average of the major and minor axis of the cross-section of the structure. For nanowires, the term “diameter” refers to the effective diameter, as defined by the average of the diameter of the cross-section of the nanowire throughout the length of the nanowire.

In some embodiments, the nanoparticle has a diameter of from 2 nm to 1,000 nm in length. In some embodiments, the nanoparticle has a diameter of from 2 nm to 100 nm in length, from 2 nm to 50 nm in length, from 2 nm to 30 nm in length, or from 2 nm to 25 nm in length. The lower range of the diameter of the nanoparticle can be at least 2 nm, 5 nm, 10 nm, or 15 nm. The upper range of the diameter of the nanoparticle can be up to 20 nm, 25 nm, 30 nm, 40 nm, 50 nm, 100 nm, 500 nm, or 1000 nm. The diameter can be within a range of any of the lower range of values and any of the upper range of values as described herein.

In some embodiments, the nanowire has a substantially uniform diameter. In some embodiments, the nanowire has a diameter or substantially uniform diameter of from 2 nm to 1,000 nm in length. In some embodiments, the nanowire has a diameter or substantially uniform diameter of from 2 nm to 100 nm in length, from 2 nm to 50 nm in length, from 2 nm to 30 nm in length, from 2 nm to 25 nm in length, or from 2 nm to 20 nm in length. The lower range of the diameter or substantially uniform diameter of the nanowire can be at least 2 nm, 5 nm, 10 nm, or 15 nm. The upper range of the diameter or substantially uniform diameter of the nanowire can be up to 20 nm, 25 nm, 30 nm, 40 nm, 50 nm, 100 nm, 500 nm, or 1000 nm. FIG. 4 shows an embodiment of the nanowires.

In some embodiments, the nanowire has a diameter of less than approximately 200 nm at its maximum point, and the diameter along the longitudinal axis preferably varies by less than approximately 10% over the section exhibiting the maximum change in diameter. Additionally, the nanostructures can have various cross-sectional shapes, including, but not limited, to circular, square, rectangular and hexagonal.

The nanostructure of the present invention can be in one of two types of structures: (a) a segregated structure, and (2) a mixed structure. In the segregated structure, the semiconductor component and the metallic component are spatially separate, such as in a lobe-lobe structure, poly-lobe structure, or a core-shell structure. In some embodiments, the lobe-lobe structure comprises a metallic component lobe and a semiconductor component lobe. In some embodiments, the core-shell structure comprises a metallic component core and a semiconductor component shell. In the mixed structure, the two components are intermixed, such as in a random binary solid solution or a homogenized mixed structure, which is a highly resistive material or is amorphous. In some embodiments, the nanostructures are nanocrystals and/or nanowires. When the metal is Sn and the semiconductor element is Ge, the lobe-lobe structure is a Sn lobe-Ge lobe structure and the core-shell structure is a Sn core-Ge shell structure.

One or more of the physical properties, such as electrical resistance and thermal resistance, of the segregated and mixed structures can be made to vary greatly between the segregated and mixed structures. The semiconductor and metallic components can be chosen to tune desired properties, such as resistivity, equilibrium melting point, and solidification kinetics, of the segregated and mixed structures.

### METHODS OF THE INVENTION

The present invention also provides for a method of changing the nanostructure from a segregated to a mixed structure and/or vice versa. This can be performed by imposition of many different influences including, but not limited to, heat, light, stress, particle radiation, and currents.

The present invention provides for a method comprising: (a) providing a composition of the present invention wherein the nanostructure is in a first structure, (b) rapid heating of the nanostructure, and (c) cooling in a controlled manner such that the nanostructure is converted into a second structure, wherein the cooling step comprises a gradual cooling or a rapid cooling. In some embodiments, the first structure is a segregated structure, the second structure is a mixed structure, and the cooling step comprises a rapid cooling. In other embodiments, the first structure is a mixed structure, the second structure is a segregated structure, and the cooling step comprises a gradual cooling.

The first structure can be a lobe-lobe structure, a mixed structure, or a core-shell structure. When the cooling step comprises a gradual cooling, the second structure is a core-shell structure. FIG. 2(b) provides a graphic representation of a gradual cooling. When the cooling step comprises a rapid cooling, the second structure is a homogenized mixed structure. FIG. 2(a) provides a graphic representation of a gradual cooling.

In some embodiments, the method comprises: (a) providing a composition of the present invention wherein the nanostructure is in a segregated structure, (b) rapid heating of the nanostructure, and (c) cooling in a controlled manner such that the nanostructure is converted into a mixed structure, wherein the cooling step comprises a rapid cooling.

In some embodiments, the method comprises: (a) providing a composition of the present invention wherein the nanostructure is in a mixed structure, (b) rapid heating of the nanostructure, and (c) cooling in a controlled manner such that the nanostructure is converted into a segregated structure, wherein the cooling step comprises a gradual cooling.

Rapid heating can be carried out using any suitable method well know to one skilled in the art. In some embodiments, the heating step comprises directing a laser to the one or more nanostructures. In some embodiments, the laser is a pulsed laser. One or more lasers can be used selectively such that each laser can at one time rapidly heat an individual nanostructure independently of the other nanostructures, such that that individual nanostructure is rapidly heated while the other nanoparticles are not.

### DEVICES AND APPLICATIONS OF THE INVENTION

The present invention provides for a memory device comprising the composition of the present invention. In some embodiments, the memory device is recordable or rewritable. Each bit can be composed of a single or multiple nanostructures. The state of the bit may be stored, for example, in the resistivity of the nanostructure. The bit information is stored in the resistivity of the nanostructures comprising the bit. The state of each nanostructure is either segregated or mixed, and the resistivity depends on the state of the nanostructure.

The invention has application in advancing rapidly static memory technology. The use of the present invention can shrink or reduce the size of such devices, and/or increase memory density and/or speed. Reliability under repeated R/W operations may also be improved.

The invention integrates well with integrated chip (IC) manufacturing methodologies. The invention provides for the fabrication of nanocrystals embedded within glass using ion implantation, which is a standard IC industry practice. These nanocrystals can exist in both an amorphous and crystalline state, and can switch between the two states using traditional heating methods possibly assisted by the application of laser light. Such nanoparticle systems offer the opportunity to generate phase-change memory elements at a much finer scale than is currently accessible. The decrease in size makes the devices more compact and faster. Further, nanocrystals can be designed with special features that enhance the changes in resistivity between the two states. Core-shell nanocrystals of the present invention are capable of generating a large difference in resistivity within a very small volume.

The ability to improve the performance of phase-change based memory devices hinges on the ability to identify new materials for which phase changes can be controlled electronically at the nanoscale and which can be fabricated using technology compatible with present (and near future) semiconductor processing methods.

Using Ion Beam Synthesis, fabricated Ge nanocrystals embedded in silica with average diameters of approximately 5 nm can undergo the phase transition. In situ transmission electron microscopy (TEM) experiments demonstrate that these nanocrystals could be repeatedly melted and resolidified (for at least a few cycles) with no apparent change in the size distribution. Further, the melting behavior displayed a very large hysteresis centered nearly on the bulk melting point. This unusual behavior was explained using classical nucleation theory (Q. Xu, I. D. Sharp, C. W. Yuan, D. O. Yi, C. Y. Liao, A. M. Glaeser, A. M. Minor, J. W. Beeman, M. C. Ridgway, P. Kluth, J. W. Ager III, D. C. Chrzan and E. E. Haller, Physical Review Letters 97, 155701/1-4 (2006)). A key prediction of this theory with direct implications for memory devices is that the kinetics of the melting phase transition are very strongly dependent on nanocrystal size. For example, Ge nanocrystals less than 2 nm in diameter embedded in SiO₂ are not expected to display a melting point hysteresis. Increasing the nanocrystal diameter to 5 nm, however, leads to a melting point hysteresis loop with a width of over 400 K.

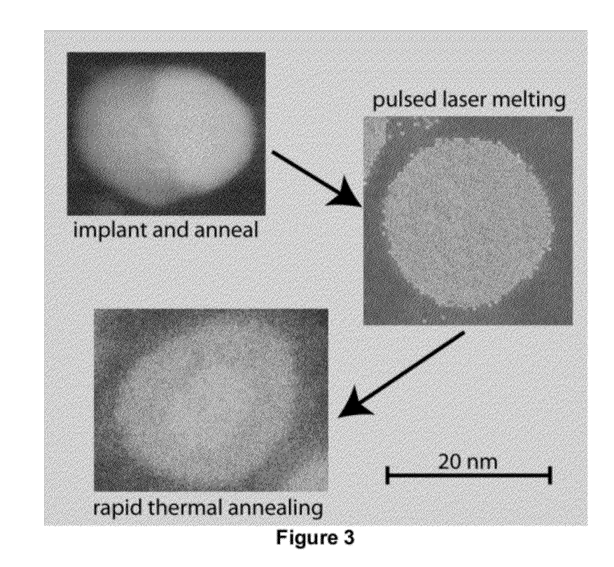

GeSn nanocrystals can be fabricated using ion beam synthesis. They can be processed into three distinct structures: Ge lobe-Sn lobe structures, homogeneously mixed structures (possibly amorphous), and Sn-core/Ge-shell structures (FIG. 3). In the processed state, the lobe-lobe structure is dominant. Application of pulsed laser melting to the lobe-lobe structure yields a homogeneous, possibly amorphous, Ge-Sn nanocluster. Subsequent rapid thermal annealing leads to a core shell structure. These experiments indicate that the kinetics of phase transformations at the nanoscale can be manipulated to create a wide variety of metastable nanostructures, nanostructures that might be useful in phase change memory applications.

One such device is shown in FIG. 4. Ordered arrays metal/semiconductor eutectic alloy nanowires can be fabricated by, for example, filling ordered arrays of nanopores in the oxide produced by anodizing aluminum. Heating above the melting point of the alloy, and slow cooling will lead to the core shell structure shown in FIG. 4(a). Since both the shell and the core are continuous, and either the core or the shell is metallic, the electrical resistance of these wires should be quite low. In contrast, heating above melting and then rapidly quenching leads to an amorphous, chemically homogeneous nanowire that is expected to have a high resistance. If contacts are connected at the top and bottom, one can fabricate a device. If the resistance change is large enough, the device might consist of one wire. However, this is not necessary—multiple wires may serve as a single bit, depending on the wire diameters. Given the sensitivity of the kinetics to geometry at the nanoscale (as evidenced by the melting transition of Ge), it is feasible to be able to select nanowire diameters and compositions to optimize reliability and thermal budgets.

The choice of matrix material, too, can play a pivotal role in controlling the kinetics. A particularly appealing idea is to fabricate the wires within a piezoelectric matrix. Then, in addition to temperature and cooling rate, we can also tune the stress state of the nanowire using an electric field. Phase transitions at the nanoscale are known to depend on stress. One skilled in the art can exploit this dependence and use electric fields to address specific bits.

It is to be understood that, while the invention has been described in conjunction with the preferred specific embodiments thereof, the foregoing description is intended to illustrate and not limit the scope of the invention. Other aspects, advantages, and modifications within the scope of the invention will be apparent to those skilled in the art to which the invention pertains.

All patents, patent applications, and publications mentioned herein are hereby incorporated by reference in their entireties.

The invention having been described, the following examples are offered to illustrate the subject invention by way of illustration, not by way of limitation.

### EXAMPLE 1

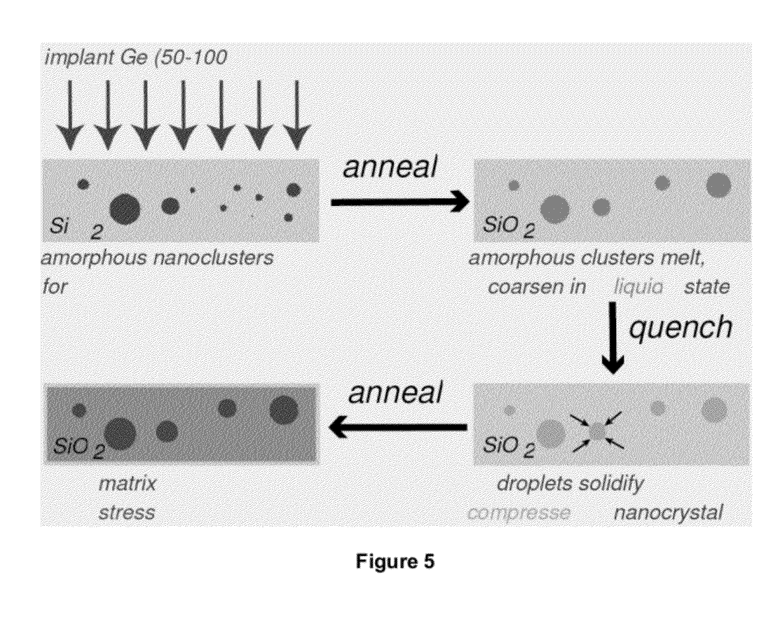

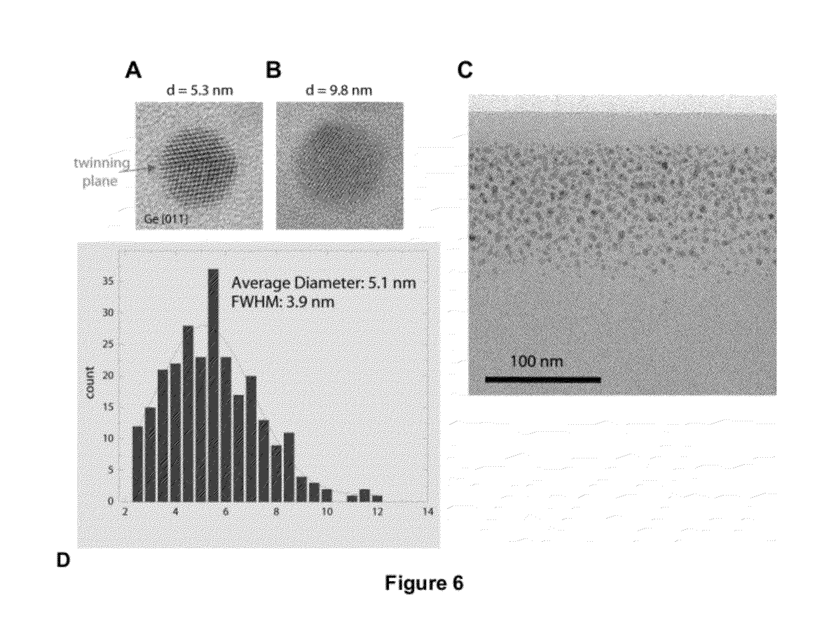

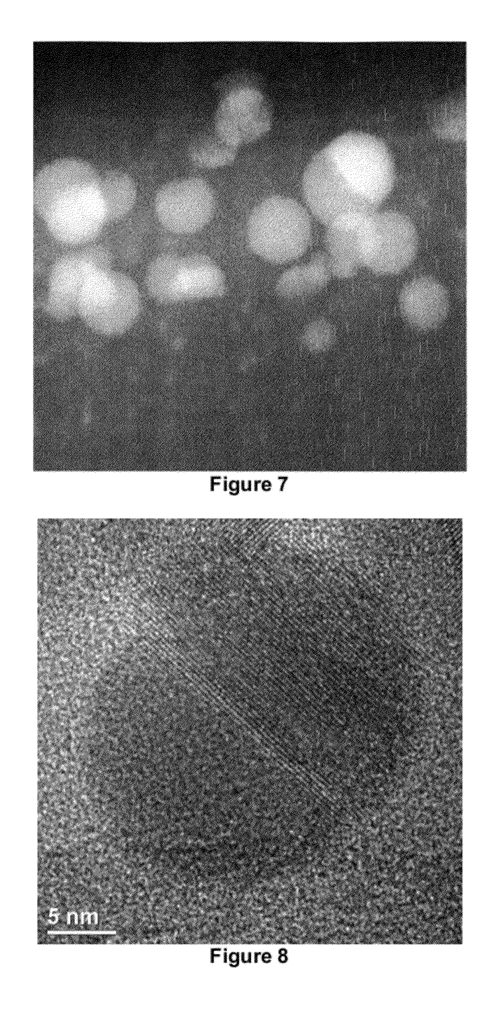

Ge and Si (4:1) are implanted into silica and annealed at 900° C. for one hour in a quartz tube. The quartz tube is then quenched in water. FIG. 5 shows the Z-contrast STEM image of the Ge-Sn alloy nanocrystals. The bright regions and dark regions correspond to Sn and Ge (or to Sn and Ge rich phases), respectively. FIG. 6 shows the high resolution image of the alloy nanocrystal. Crystalline lattice structure can be seen. Ge-Sn nanocrystals can be fabricated are processed into three distinct structures: Ge lobe-Sn lobe structures, homogeneously mixed structures (possibly amorphous), and Sn-core/Ge-shell structures (FIG. 3). In the processed state, the lobe-lobe structure is dominant. Application of pulsed laser melting to the lobe-lobe structure yields a homogeneous, possibly amorphous, Ge-Sn nanocluster. Subsequent rapid thermal annealing leads to a core shell structure. This demonstrates that the kinetics of phase transformations at the nanoscale can be manipulated to create a wide variety of metastable nanostructures, nanostructures that might be useful in phase change memory applications. A Z-contrast STEM image and a high resolution image of Ge-Sn alloy nanocrystals of the present invention are shown in FIGS. 7 and 8, respectively.

Nanocrystals in lobed-lobed structure have been converted into a homogenous mixture structure and back into the lobed-lobed structure using light and heat.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

What is claimed is:

1. A composition comprising a nanostructure comprising a semiconductor component and a metallic component, with the proviso that when the semiconductor component is Ge the metallic component is not Te; wherein the semiconductor component comprises a semiconductor that is pure, compound or doped, or an insulating element or compound, and the metallic component comprises a pure metal, metallic compound or alloy, or a degenerate semiconductor.

2. The composition of claim 1, wherein the nanostructure is in (1) a segregated structure wherein the semiconductor component and the metallic component are spatially separate, or (2) a mixed structure.

3. The composition of claim 2, wherein the nanostructure is in a segregated structure comprising a lobe-lobe structure, poly-lobe structure, or core-shell structure.

4. The composition of claim 3, wherein the segregated structure is the lobe-lobe structure comprising a metallic component lobe and a semiconductor component lobe.

5. The composition of claim 3, wherein the segregated structure is the core-shell structure comprising a metallic component core and a semiconductor component shell.

6. The composition of claim 2, wherein the nanostructure is in the mixed structure, the two components are intermixed and is a highly resistive material or is amorphous.

7. The composition of claim 1, wherein the nanostructure is a nanocrystal or a nanowire.

8. The composition of claim 1, wherein the semiconductor component and the metallic component have a low melting point, are miscible in the liquid state, and are able to segregate in the solid phase.

9. The composition of claim 1, wherein the semiconductor component and the metallic component are in a ratio such that the two components form or nearly form a eutectic alloy.

10. The composition of claim 9, wherein the eutectic alloy is a low melting point eutectic.

11. The composition of claim 10, wherein the low melting point eutectic is a temperature less than 1,000° C.

12. The composition of claim 11, wherein the low melting point eutectic is a temperature less than 750° C.

13. The composition of claim 12, wherein the low melting point eutectic is a temperature is about equal to or less than 500° C.

14. The composition of claim 1, wherein the composition further comprises a matrix wherein the nanoparticle is embedded within the matrix.

15. The composition of claim 14, wherein the matrix comprises a plurality or an array of the nanostructures, wherein each nanostructure is independently a lobe-lobe structure, mixed structure, or a core-shell structure.

16. The composition of claim 15, wherein the matrix comprises SiO₂, HfO, Al₂O₃, a glass, or any doped variety thereof.

17. The composition of claim 16, wherein the matrix consists essentially of SiO₂ or a glass.

18. The composition of claim 14, wherein the matrix is transparent, translucent, or essentially transparent.

19. The composition of claim 1, wherein the composition comprises a plurality or an array of the nanostructures, wherein the ratio of the semiconductor components to the metallic components in each plurality of nanostructures is substantially equal.

20. The composition of claim 7, wherein the nanostructure is a nanowire having a core-shell structure, wherein a first component forms the heart of the nanowire and the second component envelops the first component, or a disk multi-layer structure.

21. The composition of claim 1, wherein the semiconductor component comprises a Group IV semiconductor.

22. The composition of claim 1, wherein the semiconductor component is Si, Ge, C (diamond), SiC, GaN, GaAs, InN, CdSe, or ZnO.

23. The composition of claim 22, wherein the semiconductor component is Ge.

24. The composition of claim 23, wherein the metallic component is Sn.

25. The composition of claim 1, wherein the metallic component is Sn, Au, Ag, Al, or Cu.

26. A method of changing the nanostructure from a segregated to a mixed structure, or vice versa, comprising: (a) providing a composition of claim 1 wherein the nanostructure is in a first structure, (b) rapid heating of the nanostructure, and (c) cooling in a controlled manner such that the nanostructure is converted into a second structure, wherein the cooling step comprises a gradual cooling or a rapid cooling.

27. The method of claim 26, wherein the first structure is a segregated structure, the second structure is a mixed structure, and the cooling step comprises a rapid cooling.

28. The method of claim 27, wherein the first structure is a mixed structure, the second structure is a segregated structure, and the cooling step comprises a gradual cooling.

29. A memory device comprising the composition of claim 1.

30. The memory device of claim 29, wherein the memory device is recordable or rewritable.

31. The memory device of claim 29, wherein each bit comprises a single or multiple nanostructures.

32. The memory device of claim 31, wherein an information of a bit is stored in the resistivity of the nanostructures comprising the bit.
